(19) United States
(12) Patent Application Publication
(10) Pub. No.: US 2026/0191026 A1
(43) Pub. Date: Jul. 2, 2026

(54) MEMBER FOR SEMICONDUCTOR DEVICE PRODUCTION, AND METHOD FOR PRODUCING SAME

(71) Applicant: Resonac Corporation, Minato-ku, Tokyo (JP)

(72) Inventors: Masaya TOBA, Minato-ku, Tokyo (JP); Kazuyuki MITSUKURA, Minato-ku, Tokyo (JP)

(21) Appl. No.: 18/858,330

(22) PCT Filed: Nov. 29, 2023
(86) PCT No.: PCT/JP2023/042812

§ 371 Date: Oct. 21, 2024

(30) Foreign Application Priority Data
Dec. 27, 2022 (JP) 2022-209979

(51) Int. Cl. H10W 70/05; C23C 18/32; C23C 28/02; C25D 7/12; H10W 70/66

(52) U.S. Cl. CPC H10W 70/05; C23C 18/32; C23C 28/023; C25D 7/12; H10W 70/66

(57) ABSTRACT

A method for producing a member for semiconductor device production includes forming a recess on an insulating material layer; forming a first electroless Ni plating layer on the insulating material layer and an inner surface of the recess by electroless nickel plating; forming a Cu plating layer on the first electroless Ni plating layer; forming a wiring layer including the Cu plating layer in the recess by removing the Cu plating layer and the first electroless Ni plating layer formed on the surface of the insulating material layer; and forming a second electroless Ni plating layer on the exposed surface of the wiring layer by electroless nickel plating; in which the first electroless Ni plating layer contains nickel and boron, and a boron content of the first electroless Ni plating layer is 0.3 to 1.0 mass % based on a mass of the first electroless Ni plating layer.

### TECHNICAL FIELD

The present disclosure relates to a member for semiconductor device production and a method for producing the same.

### BACKGROUND ART

For the purpose of increasing the density and performance of semiconductor packages, a mounting form in which chips having different performances are mix-mounted in one package has been proposed, and a high-density interconnect technology between chips excellent in cost has become important (see e.g., Patent Literature 1).

Package-on-package in which different packages are multilayered on a package by flip-chip mounting to be connected has been widely adopted in smartphones and tablet terminals (see e.g., Non Patent Literature 1 and Non Patent Literature 2). As a form for mounting at a higher density, a package technology (organic interposer) using an organic substrate having high density wiring, a fan-out type package technology (FO-WLP) having a through mold via (TMV), a package technology using silicon or glass interposer, a package technology using a silicon through electrode (TSV), a package technology using a chip embedded in a substrate for inter-chip transmission, and the like have been proposed.

Particularly, in the organic interposer and the FO-WLP, when semiconductor chips are mounted in parallel, a fine wiring layer is required in order to conduct the semiconductor chips at high density (see e.g., Patent Literature 2).

### CITATION LIST

### Patent Literature

Patent Literature 1: Japanese Unexamined Patent Publication No. 2012-529770
Patent Literature 2: US 2001/0221071 A

### Non Patent Literature

Non Patent Literature 1: Application of Through Mold Via (TMV) as POP Base Package, Electronic Components and Technology Conference (ECTC), 2008
Non Patent Literature 2: Advanced Low Profile PoP Solution with Embedded Wafer Level PoP (eWLB-PoP) Technology, ECTC, 2012

### SUMMARY OF INVENTION

### Technical Problem

An organic interposer having a multilayered body (organic insulating multilayered body) formed by multilayering a plurality of organic insulating layers may be used for a build-up substrate, a wafer level package (WLP), a fan-out PoP bottom package, and the like. For example, when a plurality of fine wirings having a line width and a space width of less than or equal to 5 μm are arranged in the organic insulating multilayered body, the wirings are formed by using a trench method. The trench method is a method of forming a metal layer to be wiring in a trench (groove) formed on the surface of the organic insulating layer by a plating method or the like. Therefore, the shape of the wiring formed on the organic insulating layer follows the shape of the groove.

When fine wiring is formed in the organic insulating multilayered body by the trench method, for example, a metal material having high electrical conductivity such as copper may be used in order to reduce cost and suppress an increase in wiring resistance. When the wiring is formed using such a metal material, the metal material may diffuse into the organic insulating multilayered body. In this case, the wirings may be short-circuited by way of the diffused metal material, and there is a problem in insulation reliability of the organic interposer.

The present disclosure provides a member for semiconductor device production including a fine wiring layer having sufficiently high insulation reliability, and a method for producing the same.

### Solution to Problem

One aspect of the present disclosure relates to a method for producing a member for semiconductor device production. The production method includes (a) forming a recess on a surface of an insulating material layer; (b) forming a first electroless Ni plating layer on the surface of the insulating material layer and an inner surface of the recess by electroless nickel plating; (c) forming a Cu plating layer on the first electroless Ni plating layer; (d) forming a wiring layer including the Cu plating layer in the recess by removing the Cu plating layer and the first electroless Ni plating layer formed on the surface of the insulating material layer; and (e) forming a second electroless Ni plating layer on the exposed surface of the wiring layer by electroless nickel plating; in which the first electroless Ni plating layer contains nickel and boron, and a boron content of the first electroless Ni plating layer is 0.3 to 1.0 mass % based on a mass of the first electroless Ni plating layer.

One aspect of the present disclosure relates to a member for semiconductor device production. This member includes an insulating material layer; a recess formed on a surface of the insulating material layer; a first electroless Ni plating layer formed to cover an inner surface of the recess; a Cu plating layer formed on a surface of the first electroless Ni plating layer and with which the recess is filled; and a second electroless Ni plating layer formed to cover an exposed surface of the Cu plating layer; in which the first electroless Ni plating layer contains nickel and boron, and a boron content of the first electroless Ni plating layer is 0.3 to 1.0 mass % based on a mass of the first electroless Ni plating layer.

### Advantageous Effects of Invention

According to the present disclosure, a member for semiconductor device production having a fine wiring layer with a sufficiently high insulation reliability and a method for producing the same are provided.

### BRIEF DESCRIPTION OF DRAWINGS

(a) in FIG. 1 is a cross-sectional view schematically illustrating a state in which an insulating material layer is formed on a support, (b) in FIG. 1 is a cross-sectional view schematically illustrating a state in which a recess is formed in the insulating material layer, (c) in FIG. 1 is a cross-sectional view schematically illustrating a state in which a palladium catalyst adsorption layer is formed on a surface of the insulating material layer by pretreatment, and (d) FIG. 1 is a cross-sectional view schematically illustrating a state in which a first electroless Ni plating layer is formed on the insulating material by electroless nickel plating.

(a) in FIG. 2 is a cross-sectional view schematically illustrating a state in which a Cu plating layer is formed on the first electroless Ni plating layer, (b) in FIG. 2 is a cross-sectional view schematically illustrating a state in which a wiring layer is exposed by surface polishing, and (c) in FIG. 2 is a cross-sectional view schematically illustrating a state in which a second electroless Ni plating layer is formed so as to cover the exposed wiring layer.

FIG. 3 is an SEM image showing a trench pattern according to a first example.

(a) FIG. 4 is an SEM image showing a Ni—B seed layer (first electroless Ni plating layer) formed on a surface of an insulating material layer and an inner surface of a trench, and (b) in FIG. 4 is a partially enlarged view of (a) in FIG. 4.

(a) in FIG. 5 is a plan view schematically illustrating a configuration of a comb-shaped electrode according to an example and a comparative example, and (b) in FIG. 5 is a cross-sectional view schematically illustrating a sample used for evaluation of electrical insulation property.

### DESCRIPTION OF EMBODIMENTS

Hereinafter, embodiments of the present disclosure will be described in detail with reference to the drawings. In the following description, the same or corresponding portions are denoted by the same reference numerals, and redundant description will be omitted. Furthermore, unless otherwise specified, the positional relationship such as up, down, left, and right is based on the positional relationship illustrated in the drawings. Furthermore, the dimensional ratios in the drawings are not limited to the illustrated ratios.

The use of the terms “left”, “right”, “front”, “back”, “up”, “down”, “above”, “below”, and the like in the description and claims of this specification is intended for description and is not necessarily meant to be a permanent relative position thereof. In addition, the term “layer” includes not only a structure having a shape formed on the entire surface but also a structure having a shape formed in one part thereof when observed as a plan view.

The present embodiment is particularly suitable in a form in which miniaturization and multiple pins are required, and is particularly suitable in a package form in which an interposer for mix-mounting different types of chips is required. More specifically, the production method according to the present embodiment is suitable in a package form having a trench structure in which a line width is less than or equal to 20 μm (e.g., 0.5 to 10 μm in the case of finer lines) and a space width is less than or equal to 20 μm (e.g., 0.5 to 10 μm in the case of finer lines).

The method for producing the member for semiconductor device production according to the present embodiment includes the following steps.
(I) forming an insulating material layer 1 on a support S
(II) forming a recess 1a on a surface of the insulating material layer 1
(III) modifying the surface including the recess 1a of the insulating material layer 1
(IV) forming a palladium adsorption layer 3 on the surface including the recess 1a of modified insulating material layer 1
(V) forming a first electroless Ni plating layer 5 by electroless nickel plating on the surface including the recess 1a of the insulating material layer 1 on which the palladium adsorption layer 3 is formed
(VI) forming a Cu plating layer 7 on the first electroless Ni plating layer 5 by copper electroplating
(VII) forming a wiring layer 8 including the Cu plating layer 7 formed in the recess 1a by removing the Cu plating layer 7, the first electroless Ni plating layer 5, and the palladium adsorption layer 3 formed in a region (on the upper surface of the insulating material layer 1) other than the recess 1a in the surface of the insulating material layer 1
(VIII) forming second electroless Ni plating layer 9 on an exposed surface 8a of the wiring layer 8 by electroless nickel plating

According to the above production method, diffusion of copper contained in the wiring layer 8 can be prevented by the first electroless Ni plating layer 5 and the second electroless Ni plating layer 9, so that a member for semiconductor device production having a fine wiring layer with a sufficiently high insulation reliability can be produced. Each step will be described below.

### <(I) Forming an Insulating Material Layer on a Support>

First, step (I) of forming the insulating material layer 1 on the support S of the member for semiconductor device production is performed ((a) in FIG. 1). The support S is not particularly limited, but is a silicon plate, a glass plate, an SUS plate, a substrate containing glass cloth, a sealing resin containing a semiconductor element, or the like, and a substrate having high rigidity is preferable.

The thickness of the support S is preferably in the range of 0.2 mm to 2.0 mm. If it is thinner than 0.2 mm, handling becomes difficult, whereas if it is thicker than 2.0 mm, the material cost tends to increase. The support S may have a wafer shape or a panel shape. The size is not particularly limited, but a wafer having a diameter of 200 mm, a diameter of 300 mm, or a diameter of 450 mm, or a rectangular panel in which one side is 300 to 700 mm is preferably used.

A photosensitive resin material is preferably employed as a material constituting the insulating material layer 1 from the viewpoint that a fine recess 1a can be easily formed by a photolithography process in step (II) described later. Examples of the photosensitive insulating material include a liquid or film-like material, and a film-like photosensitive insulating material is preferable from the viewpoint of film thickness flatness and cost. In addition, the photosensitive insulating material preferably contains a filler (filler) having an average particle size of less than or equal to 500 nm (more preferably, 50 to 200 nm) from the viewpoint of being able to form fine wiring. The filler content of the photosensitive insulating material is preferably 0 to 70 parts by mass, and more preferably 0 to 50 parts by mass, with respect to 100 parts by mass of the mass of the photosensitive insulating material excluding the filler.

When a film-like photosensitive insulating material is used, the lamination step is preferably performed at a temperature as low as possible, and a photosensitive insulating film that can be laminated at 40° C. to 120° C. is preferably employed. A photosensitive insulating film that can be laminated at a temperature lower than 40° C. tends to have strong tackiness at normal temperature (about 25° C.) and poor handleability, and a photosensitive insulating film that can be laminated at a temperature higher than 120° C. tends to have large warpage after lamination.

The coefficient of thermal expansion of the insulating material layer 1 after curing is preferably less than or equal to 80×10⁻⁶/K from the viewpoint of suppressing warpage, and more preferably less than or equal to 70×10⁻⁶/K from the viewpoint of obtaining high reliability. In addition, it is preferably greater than or equal to 20×10⁻⁶/K from the viewpoint of stress relaxation property of the insulating material and obtaining a high-definition pattern.

The thickness of the insulating material layer 1 is preferably less than or equal to 10 μm, more preferably less than or equal to 5 μm, and still more preferably less than or equal to 3 μm. When the thickness of the insulating material layer 1 is within the above range, for example, the recess 1a having a fine trench structure is easily formed in step (II) described later. The thickness of the insulating material layer 1 is preferably greater than or equal to 1 μm from the viewpoint of insulation reliability.

### <(II) Forming a Recess in the Insulating Material Layer>

Next, a step (II) of forming a recess 1a on the surface of the insulating material layer 1 is performed ((b) in FIG. 1). In the present embodiment, the recess 1a refers to a portion recessed in the thickness direction of the insulating material layer 1 with respect to the surface of the insulating material layer 1, and includes an inner wall (side surface, bottom surface, etc.) of the recessed portion. As illustrated in (b) in FIG. 1, it is preferable that the recess 1a is formed so as to reach the surface of the support S, that is, the recess 1a is constituted by a side surface formed of the insulating material layer 1 and a bottom surface formed of the surface of the support S. The recess 1a preferably has a trench structure, and in this case, the opening width (line width) may be, for example, 0.5 to 20 μm, and may be 0.5 to 5 μm in a case where the recess 1a is finer. It tends to be easy to provide a semiconductor device that realizes high density by setting the opening width of the recess 1a to the above range. That is, it is easy to produce a semiconductor device having a fine wiring layer at a good yield and at a low cost. Note that the opening shape of the recess 1a may be, for example, a circular shape or an elliptical shape, and the opening size in this case may be an extent corresponding to the area of a circle having a diameter of 5 to 50 μm (a diameter of 5 to 10 μm in a finer case).

Examples of the method for forming the recess 1a include laser ablation, photolithography, and imprinting, but from the viewpoint of miniaturization and cost, it is preferable that the insulating material layer 1 made of a photosensitive resin material is formed in step (I), and the recess 1a is formed by a photolithography process (exposure and development). As a method for exposing the photosensitive resin material, a normal projection exposure method, a contact exposure method, a direct drawing exposure method or the like can be used, and as a development method, it is preferable to use an alkali aqueous solution of sodium carbonate or TMAH (tetramethylammonium hydroxide). After the recess 1a is formed in the insulating material layer 1, the insulating material may be further heated and cured. The heating temperature is 100° C. to 200° C., and the heating time is 30 minutes to 3 hours.

### <(III) Modifying Surface>

Next, a step (III) of modifying the surface including the recess 1a of the insulating material layer 1 is performed (not illustrated). In the present embodiment, modification means that the surface of the insulating material layer 1 is brought into a state in which the palladium catalyst is more easily adsorbed prior to step (IV). Since the modification treatment is performed before step (IV), the modification treatment may be hereinafter referred to as “pretreatment”.

As the modification method, either a pretreatment by the following wet method or a pretreatment by the dry method can be used. Examples of the pretreatment liquid (modification liquid) used in the pretreatment in the wet method include a liquid containing at least one selected from a group consisting of silane coupling agent containing polyether, glycol ether, amine, amide, ureide, triazine, melamine, imidazole, triazole, benzotriazole, and the like in the molecule. The type of solvent used in these pretreatment liquids is not particularly limited, and can be selected from generally used organic solvents and water, and one solvent may be used alone, or two or more solvents may be used in combination. In addition, a surfactant may be contained for the purpose of improving the wettability of the surface of the insulating material layer 1. In addition, in order to enhance the modifying effect, pretreatment may be performed with an aqueous solution containing sodium hypophosphite, potassium hypophosphite, calcium hypophosphite, or the like. Furthermore, examples of a modification method by pretreatment in a wet method other than these include a roughening treatment with an acid or an alkali. On the other hand, examples of the pretreatment in the dry method include surface modification by plasma treatment, corona treatment, ultraviolet treatment, or the like.

Among the above-described modification methods, it is preferable to perform, as a pretreatment, modification of the surface of the insulating material layer 1 with a pretreatment liquid (modification liquid) containing a silane coupling agent, which is a pretreatment in a wet method. Specific examples of the method for carrying out the wet method include a spraying method, a dipping method, a spin coating method, and a printing method in which a pretreatment liquid is brought into contact with the surface of the insulating material layer 1, and a dipping method capable of efficiently performing the treatment is preferable.

In order to increase the reactivity between the components of the pretreatment liquid and the insulating material layer 1, the surface of the insulating material layer 1 may be activated before performing the pretreatment for these modifications. Examples of the activation method include methods such as ultraviolet irradiation, electron beam irradiation, ozone water treatment, corona discharge treatment, and plasma treatment, but ultraviolet irradiation that does not require vacuum equipment and does not generate waste liquid and the like is preferable.

Examples of the ultraviolet irradiation lamp used for activation include a high pressure mercury lamp, a low pressure mercury lamp, and a vacuum ultraviolet excimer lamp, and a low pressure mercury lamp or an excimer lamp having a large activation effect is preferable. The activation is preferably performed in the atmosphere, and more preferably performed in an oxygen atmosphere. The activation is preferably performed at 25° C. to 100° C. In order to further accelerate the reactivity, 40° C. to 100° C. is more preferable, and 60° C. to 100° C. is still more preferable.

The contact angle of the surface of the insulating material layer 1 after activation with pure water is preferably less than or equal to 40 degrees, more preferably less than or equal to 20 degrees, and still more preferably less than or equal to 10 degrees. Furthermore, the activation treatment may be repeated a plurality of times.

The pretreatment is preferably performed at 25° C. to 80° C. In order to further accelerate the reactivity, 40° C. to 80° C. is more preferable, and 60° C. to 80° C. is still more preferable. The pretreatment is preferably performed in 5 minutes to 30 minutes. In order to further accelerate the reactivity, the time is more preferably 10 minutes to 30 minutes, and still more preferably 15 minutes to 30 minutes. After the pretreatment liquid used in the pretreatment is brought into contact, washing may be performed with water or an organic solvent to remove excess pretreatment liquid.

After the pretreatment is performed, a heat treatment may be performed in order to increase the bonding strength between the insulating material layer 1 and the silane coupling agent which is a component of the pretreatment liquid. The heat treatment temperature is preferably 80° C. to 200° C. In order to further accelerate the reactivity, the temperature is more preferably 120° C. to 200° C., and further preferably 120° C. to 180° C. The heat treatment time is preferably 5 minutes to 60 minutes, more preferably 10 minutes to 60 minutes, and still more preferably 20 minutes to 60 minutes. In addition, the pretreatment and the heat treatment may be repeated a plurality of times.

### <(IV) Forming Palladium Adsorption Layer>

Next, a step (IV) of forming the palladium adsorption layer 3 on the surface including the recesses 1a of the modified insulating material layer 1 is performed ((c) in FIG. 1). In the present embodiment, the palladium adsorption layer 3 adsorbs palladium on the surface including the recess 1a of the insulating material layer 1, then performs activation for causing palladium to act as a catalyst, and serves as a catalyst for the electroless plating reaction of electroless nickel plating performed in the subsequent step. A method for forming the palladium adsorption layer 3 will be described below.

First, palladium is adhered on the surface of the insulating material layer 1 after the pretreatment. Palladium may be a commercially available palladium aqueous solution for electroless plating, and a solution (palladium-tin colloid solution) in which a palladium-tin colloid is dispersed in water, a palladium ion aqueous solution, a palladium nanoparticle dispersion solution, or the like may be used. The temperature of the aqueous solution to be immersed for adhering palladium is 25° C. to 80° C., and the immersion time for adhering palladium is 1 minute to 60 minutes. After palladium is adhered, washing may be performed with water or an organic solvent in order to remove excess palladium.

After palladium is adhered, activation is performed to cause palladium to act as a catalyst. The reagent for activating palladium may be a commercially available activating agent (activation treatment liquid). The temperature of the activating agent immersed to activate palladium is 25° C. to 80° C., and the time of immersion to activate palladium is 1 minute to 60 minutes. After activation of palladium, it may be washed with water or an organic solvent to remove excess activating agent.

### <(V) Forming First Electroless Ni Plating Layer>

Subsequently, a step (V) of forming the first electroless Ni plating layer 5 by electroless nickel plating on the surface including the recess 1a of the insulating material layer 1 on which the palladium adsorption layer 3 has been formed is performed ((d) in FIG. 1). The first electroless Ni plating layer 5 serves as a seed layer for copper electroplating (a power supply layer for copper electroplating) to be performed for forming the Cu plating layer 7 in a subsequent step.

Examples of the electroless nickel plating include electroless pure nickel plating (purity of greater than or equal to 99 mass %), electroless nickel-phosphorus plating (phosphorus content: 1 mass % to 13 mass %), and electroless nickel-boron plating (boron content: 0.3 mass % to 1.0 mass %), and electroless nickel-boron plating is preferable from the viewpoint of management stability of a plating bath. The boron content of the first electroless Ni plating layer 5 is preferably 0.3 to 1.0 mass %. If this value is less than 0.3 mass %, the electrical characteristics tend to be insufficient due to the magnetization characteristics, and the reliability tends to be insufficient, and on the other hand, if this value exceeds 1 mass %, the electrical conductivity tends to deteriorate, and the electrical characteristics tend to be insufficient. This value is preferably 0.3 to 0.8 mass % and more preferably 0.3 to 0.5 mass %. The nickel content of the first electroless Ni plating layer 5 is, for example, 98.0 to 99.7 mass %, and may be 99.5 to 99.7 mass %.

The electroless nickel plating solution may be a commercially available plating solution, and for example, TOP CHEMIALOY B-1 (Okuno Pharmaceutical Co., Ltd.) can be used. The electroless nickel plating is performed in an electroless nickel plating solution at 60° C. to 90° C.

The thickness of the first electroless Ni plating layer 5 is preferably 20 to 400 nm, more preferably 40 to 300 nm, and still more preferably 60 to 250 nm. When the thickness of the first electroless Ni plating layer 5 is greater than or equal to 20 nm, the effect of suppressing diffusion of copper is easily sufficiently obtained, and on the other hand, when the thickness of the first electroless Ni plating layer 5 is less than or equal to 400 nm, the overall thickness can be easily thinned when a semiconductor device is produced by multilayering a wiring layer.

The first electroless Ni plating layer 5 preferably satisfies the following conditions.

$$0.3 \leq T a / T \leq 1.0$$

Ta represents the thickness of the first electroless Ni plating layer 5 formed on the inner surface of the recess 1a, and T represents the thickness of the first electroless Ni plating layer 5 formed on the surface of the insulating material layer 1. The inner surface of the recess 1a means the bottom surface and the side surface of the recess 1a. When the value of Ta/T is less than 0.3, the Cu ion migration resistance tends to be insufficient, and on the other hand, when the value of Ta/T exceeds 1.0, the electrical conductivity of the wiring tends to be insufficient. This value is more preferably 0.6 to 1.0 and still more preferably 0.8 to 1.0.

After the electroless nickel plating, washing may be performed with water or an organic solvent to remove excess plating solution. In addition, after the electroless nickel plating, heat curing (annealing: aging curing treatment by heating) may be performed in order to increase the adhesion between the first electroless Ni plating layer 5 and the insulating material layer 1. The heat curing temperature is preferably 80° C. to 200° C. In order to further accelerate the reactivity, the temperature is more preferably 120° C. to 200° C., and further preferably 120° C. to 180° C. The heat curing time is preferably 5 minutes to 60 minutes, more preferably 10 minutes to 60 minutes, and still more preferably 20 minutes to 60 minutes.

### <(VI) Forming Cu Plating Layer>

Next, a step (VI) of forming the Cu plating layer 7 on the first electroless Ni plating layer 5 by copper electroplating is performed ((a) in FIG. 2). Specifically, the first electroless Ni plating layer 5 formed by electroless nickel plating is used as a seed layer, and the Cu plating layer 7 is formed on the first electroless Ni plating layer 5 by copper electroplating, and the recess 1a whose inner wall is covered with the first electroless Ni plating layer 5 is filled with the Cu plating layer 7. Note that in the present embodiment, copper electroplating is used as a method for forming the Cu plating layer 7, but other than this, for example, electroless copper plating can be selected.

The thickness of the Cu plating layer 7 (excluding the region where the recess 1a is formed) is preferably 1 to 10 μm, more preferably 1 to 5 μm, and still more preferably 1 to 3 μm.

When the recess 1a is in a state filled with the Cu plating layer 7, in the next step (VII), the surface of the insulating material layer 1 and the wiring layer 8 (constituted by the Cu plating layer 7, the first electroless Ni plating layer 5, and the palladium adsorption layer 3) formed in the recess 1a can be made flush with each other only by removing the Cu plating layer 7, the first electroless Ni plating layer 5, and palladium (palladium adsorption layer) remaining thereunder formed in a region other than the recess 1a on the surface of the insulating material layer 1. In order to have the recess 1a in a state filled with the Cu plating layer 7 by copper electroplating, it is preferable to use so-called filled plating in which the deposition amount of copper electroplating in the recess 1a (plating thickness) is larger than that on the surface of the insulating material layer 1.

Note that the recess 1a may not necessarily be filled with the Cu plating layer 7, and the Cu plating layer 7 may be formed along the inner wall (side surface and bottom surface) of the recess 1a. In this case, in the next step (VII), the Cu plating layer 7, the first electroless Ni plating layer 5, and palladium (palladium adsorption layer) remaining thereunder formed in the region other than the recess 1a on the surface of the insulating material layer 1 are removed, and then the surface of the insulating material layer 1 is further ground to expose the Cu plating layer 7 formed on the bottom surface of the recess 1a, so that the surface of the insulating material layer 1 and the wiring layer 8 formed in the recess 1a can be made flush with each other.

<(VII) Forming Wiring Layer including Cu Plating Layer>

Next, a step (VII) of forming the wiring layer 8 including the Cu plating layer 7 formed in the recess 1a is performed by removing the Cu plating layer 7, the first electroless Ni plating layer 5, and the palladium adsorption layer 3 formed in the region other than the recess 1a on the surface of the insulating material layer 1 ((b) in FIG. 2). That is, by removing the Cu plating layer 7, the first electroless Ni plating layer 5, and palladium (palladium adsorption layer 3) remaining thereunder formed on the upper surface of the insulating material layer 1, a part of the Cu plating layer 7, the first electroless Ni plating layer 5, and the palladium adsorption layer 3 is left in the recess 1a. As a result, the wiring layer 8 constituted by the Cu plating layer 7, the first electroless Ni plating layer 5, and the palladium adsorption layer 3 is formed in the recess 1a.

When removing the Cu plating layer 7, the first electroless Ni plating layer 5, and palladium remaining thereunder formed on the upper surface of the insulating material layer 1, it is preferable to treat the surface of the insulating material layer 1 and the wiring layer 8 in the recess 1a so as to be flush with each other. In other words, after step (VII), step (VII) is preferably performed so that the surface of the insulating material layer 1 and the wiring layer 8 in the recess 1a form a flat surface. The removal treatment in step (VII) may be performed only on the Cu plating layer 7, the first electroless Ni plating layer 5, and palladium remaining thereunder formed on the upper surface of the insulating material layer 1, or in addition, may be performed on a part of the upper surface side of the insulating material layer 1.

Examples of the removal treatment in step (VII) include a back grinding method, a fly cut method, chemical mechanical polishing (CMP), and the like, and one of these may be used alone, or two or more thereof may be used in combination. For example, in the fly cut method, a grinding device using a diamond cutting tool may be used. As a specific example, an automatic surface planer (produced by DISCO Corporation, Trade name “DAS 8930”) corresponding to a 300 mm wafer can be used. Note that the removal treatment by the fly cut method can also be said to be a flattening treatment because the entire surface of the Cu plating layer 7 is uniformly polished from the upper surface side, and the polished surface is flattened.

### <(VIII) Forming Second Electroless Ni Plating Layer>

Next, a step (VIII) of forming a second electroless Ni plating layer 9 by electroless nickel plating on the exposed surface 8a of the wiring layer 8 formed by the removal treatment in step (VII) is performed ((c) in FIG. 2). Thus, the wiring substrate 10 (member for semiconductor device production) is produced. For example, the second electroless Ni plating layer 9 can be formed only on the exposed surface 8a by performing degreasing, water washing, sulfuric acid cleaning, palladium catalysis, and nickel plating on the exposed surface 8a of the wiring layer 8 in this order. As a plating solution for electroless nickel plating, a commercially available substituted electroless plating solution can be applied.

Examples of the electroless nickel plating include electroless pure nickel plating (purity of greater than or equal to 99 mass %), electroless nickel-phosphorus plating (phosphorus content: 1 mass % to 13 mass %), and electroless nickel-boron plating (boron content: 0.3 mass % to 1.0 mass %). Among them, electroless nickel-phosphorus plating is preferable from the viewpoint of selectively film-forming an electroless plated film on Cu. The phosphorus content of the second electroless Ni plating layer 9 is preferably 1 to 13 mass %. If this value is less than 1 mass %, the electrical characteristics tend to be insufficient due to the magnetization characteristics, and the reliability tends to be insufficient, and on the other hand, if this value exceeds 13 mass %, the electrical conductivity tends to deteriorate, and the electrical characteristics tend to be insufficient. This value is preferably 1 to 10 mass % and more preferably 1 to 8 mass %. The nickel content of the second electroless Ni plating layer 9 is, for example, 88 to 99 mass %, and may be 92 to 99 mass %.

The electroless nickel plating solution may be a commercially available plating solution, and for example, a medium phosphorus type (phosphorus content: 7 mass % to 9 mass %) electroless nickel plating solution (produced by SANMEI Co., Ltd., Trade names “ICP Nicolon GM-SB-M” and “ICP Nicolon GMSD”) can be used. The electroless nickel plating is performed in an electroless nickel plating solution at 60° C. to 90° C.

Diffusion of copper contained in the wiring layer 8 can be sufficiently suppressed by covering the exposed surface 8a of the wiring layer 8 with the second electroless Ni plating layer 9. Therefore, the wiring substrate 10 is useful for producing a semiconductor device having a fine wiring layer with sufficiently high insulation reliability. The thickness of the second electroless Ni plating layer 9 is preferably 50 to 500 nm, more preferably 100 to 400 nm, and still more preferably 150 to 300 nm. When the thickness of the second electroless Ni plating layer 9 is greater than or equal to 50 nm, the effect of suppressing diffusion of copper is easily sufficiently obtained, and on the other hand, when the thickness is less than or equal to 500 nm, the overall thickness can be easily thinned when a semiconductor device is produced by multilayering a wiring layer.

The wiring substrate 10 includes the insulating material layer 1, the recess 1a, the first electroless Ni plating layer 5 formed so as to cover the inner surface of the recess 1a, the Cu plating layer 7 with which the recess 1a is filled, and the second electroless Ni plating layer 9 formed so as to cover an exposed surface of the Cu plating layer 7. The first electroless Ni plating layer 5 and the Cu plating layer 7 constitute the wiring layer 8.

Although the member for semiconductor device production (wiring substrate) has been described above, the present invention is not necessarily limited to the above-described embodiments, and modifications may be appropriately made without departing from the gist of the present invention.

For example, in the above embodiment, the method of producing the wiring substrate 10 having one wiring layer has been exemplified, but instead of the wiring substrate 10, a wiring substrate having a multilayered wiring layer may be produced, and a semiconductor device may be produced using the same. The multilayered wiring layer can be formed by repeating, one or more times, step (XI) of forming an insulating material layer so as to cover the insulating material layer 1 and the second electroless Ni plating layer 9 after step (VIII), and a series of steps from step (II) to step (VIII). For the formation of the insulating material layer in step (XI), the same material as that of the insulating material layer 1 described above may be used, and a photosensitive insulating material is preferable. The insulating material layer may be formed in the same manner as the insulating material layer 1. The thickness of the insulating material layer is preferably less than or equal to 10 μm, more preferably less than or equal to 5 μm, and still more preferably less than or equal to 3 μm.

In the above embodiment, a case where the insulating material layer is a single layer has been exemplified, but the insulating material layer may have a multilayered structure. That is, the insulating material layer may be formed through the following steps, and may include a first insulating layer and a second insulating layer formed on a surface of the first insulating layer, and a recess may be formed in the second insulating layer. In this case, the bottom surface of the recess is constituted by the surface of the first insulating layer.
(a1) curing the first insulating layer by exposing the first insulating layer formed of the negative photosensitive resin composition.
(a2) forming a second insulating layer formed of a negative photosensitive resin composition on the surface of the first insulating layer after curing.
(a3) exposing a region of the second insulating layer where a recess is to be formed.
(a4) forming a recess by developing the exposed second insulating layer.

The present disclosure relates to the following inventions.
[1] A method for producing a member for semiconductor device production, the method including:
(a) forming a recess on a surface of an insulating material layer;
(b) forming a first electroless Ni plating layer on the surface of the insulating material layer and an inner surface of the recess by electroless nickel plating;
(c) forming a Cu plating layer on the first electroless Ni plating layer;
(d) forming a wiring layer including the Cu plating layer in the recess by removing the Cu plating layer and the first electroless Ni plating layer formed on the surface of the insulating material layer; and
(e) forming a second electroless Ni plating layer on an exposed surface of the wiring layer by electroless nickel plating,
wherein the first electroless Ni plating layer contains nickel and boron, and a boron content of the first electroless Ni plating layer is 0.3 to 1.0 mass % based on a mass of the first electroless Ni plating layer.
[2] The method for producing a member for semiconductor device production according to [1], wherein the second electroless Ni plating layer contains nickel and phosphorus, and a phosphorus content of the second electroless Ni plating layer is 1 to 13 mass % based on a mass of the second electroless Ni plating layer.
[3] The method for producing a member for semiconductor device production according to [1] or [2], wherein the first electroless Ni plating layer formed in step (b) satisfies the following conditions:

$$0.3 \leq T a / T \leq 1.0$$

Ta represents the thickness of the first electroless Ni plating layer formed on the inner surface of the recess, and T represents the thickness of the first electroless Ni plating layer formed on the surface of the insulating material layer.
[4] The method for producing a member for semiconductor device production according to any one of [1] to [3], wherein step (a) includes:
(a1) curing a first insulating layer by exposing the first insulating layer formed of a negative photosensitive resin composition;
(a2) forming a second insulating layer formed of a negative photosensitive resin composition on a surface of the first insulating layer after curing;
(a3) exposing a region of the second insulating layer where the recess is to be formed; and
(a4) forming the recess by developing the second insulating layer after exposure.
[5] A member for semiconductor device production including:
an insulating material layer;
a recess formed on a surface of the insulating material layer;
a first electroless Ni plating layer formed so as to cover an inner surface of the recess;
a Cu plating layer formed on a surface of the first electroless Ni plating layer and with which the recess is filled; and
a second electroless Ni plating layer formed so as to cover an exposed surface of the Cu plating layer, wherein
the first electroless Ni plating layer contains nickel and boron, and
a boron content of the first electroless Ni plating layer is 0.3 to 1.0 mass % based on a mass of the first electroless Ni plating layer as a reference thereof.
[6] The member for semiconductor device production according to [5], wherein
the second electroless Ni plating layer contains nickel and phosphorus, and
a phosphorus content of the second electroless Ni plating layer is 1 to 13 mass % based on a mass of the second electroless Ni plating layer as a reference thereof.
[7] The member for semiconductor device production according to [5] or [6], wherein the recess is a groove having an opening width of 0.5 to 3 μm.
[8] The member for semiconductor device production according to any one of [5] to [7], wherein a thickness of the insulating material layer is less than or equal to 10 μm.

### EXAMPLES

Hereinafter, the present disclosure will be described based on examples. It should be noted that the present invention is not limited to the following examples.

### First Example

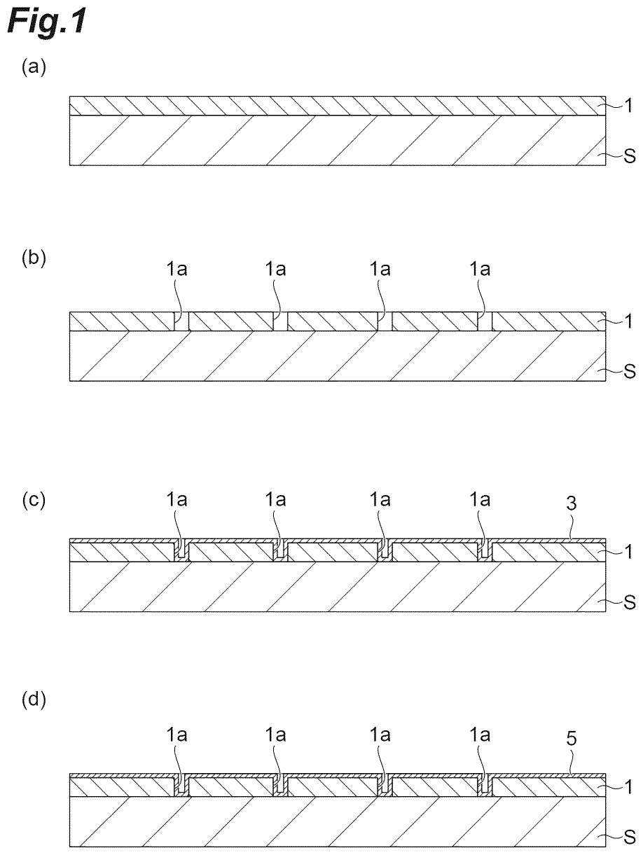

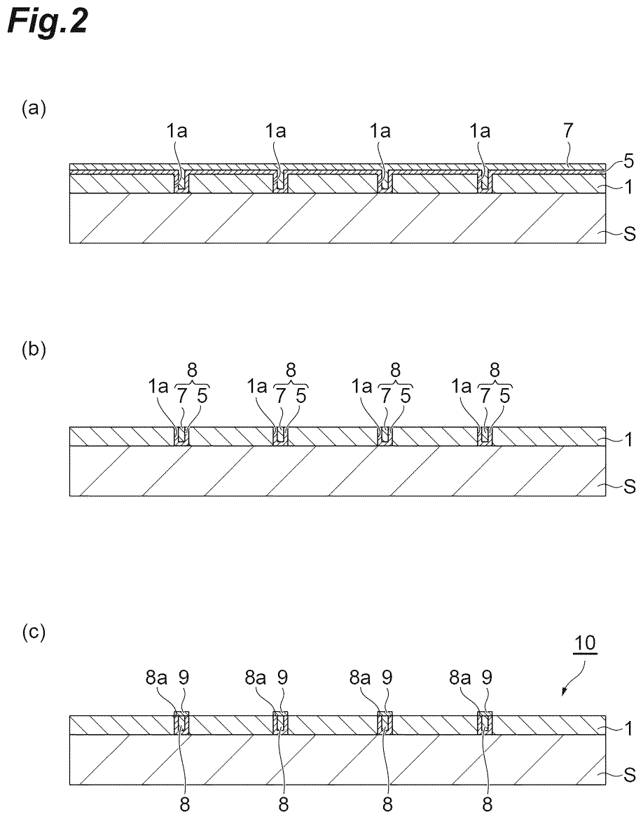

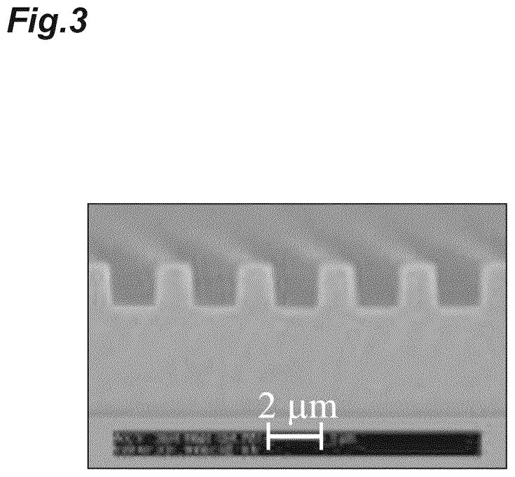

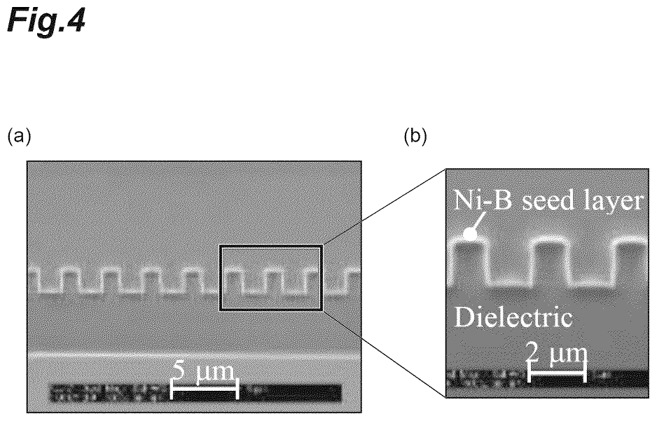

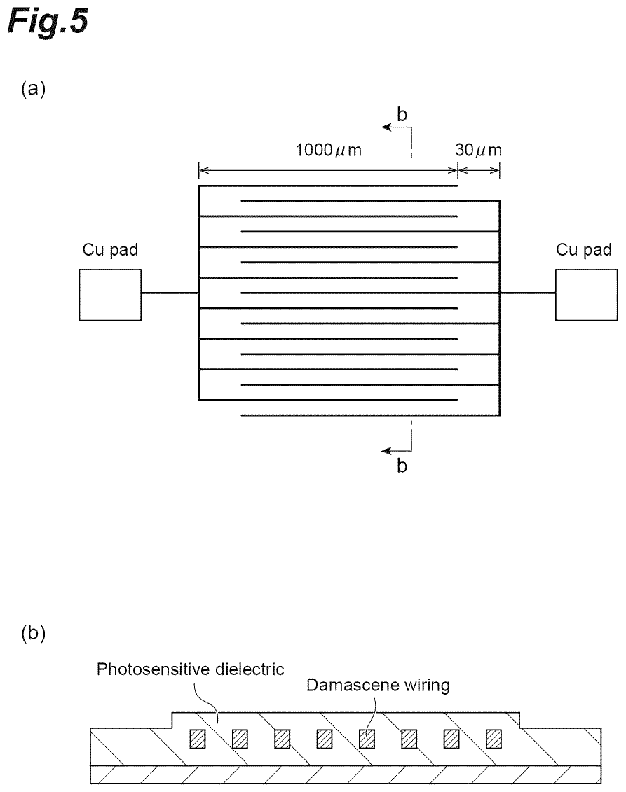

A layer of a negative photosensitive insulating material (thickness: 2 μm) was formed on the surface of the silicon wafer. The entire surface of this layer was exposed to i-line of broadband using a high-pressure mercury lamp, and then heated on a hot plate at 85° C. After development with 2.38% TMAH (Tetra-methyl ammonium hydroxide), the first insulating layer was formed by heat curing. Next, a layer (thickness: 2 μm) of the same photosensitive insulating material as that of the first insulating layer was formed on the surface of the first insulating layer. Exposure was performed using an i-line stepper so as to form a trench pattern in this layer. After the exposure, it was heated on a hot plate. After development with 2.38% TMAH, a second insulating layer having a trench pattern was formed by heat curing. As a result, an insulating material layer (thickness: 4 μm) composed of the first insulating layer and the second insulating layer was obtained. The L/S (width/space) of the trench pattern was 1.2 μm/1.2 μm (see FIG. 3).

A Ni—B seed layer (first electroless Ni plating layer) having a thickness of 200 nm was formed on the surface of the second insulating layer and the inner surface of the trench (side surface and bottom surface of the trench) by an electroless Ni—B plating process (see (a) and (b) in FIG. 4). The Ni—B seed layer had a boron content of 0.4 mass % and a nickel content of 99.6 mass %. All the contents mentioned herein are based on the mass of the Ni—B seed layer. Note that “Ni—B seed layer” in (b) in FIG. 4 means a Ni—B seed layer, and “Dielectric” means a dielectric layer (insulating material layer).

Next, a Cu plating layer having a thickness of 5 μm was formed on the Ni—B seed layer by electrolytic Cu plating. Thus, the inside of the trench pattern was filled with the Cu plating layer. Thereafter, the excess Cu plating layer and Ni—B seed layer were ground by CMP, and a part of the surface of the second insulating layer was ground. After grinding, a metal cap (second electroless Ni plating layer) having a thickness of 200 nm was formed on the exposed surface of the Cu plating layer by an electroless Ni—P plating process. The metal cap had a phosphorus content of 5 mass % and a nickel content of 95 mass %. All the contents mentioned herein are based on the mass of the metal cap. A photosensitive insulating material layer (thickness: 3 μm) was formed so as to cover the metal cap. Through the above steps, a comb-shaped electrode having the configuration illustrated in (a) and (b) in FIG. 5 was formed on the surface of a silicon wafer. In (a) in FIG. 5, “Cu pad” means a Cu pad. “Photosensitive dielectric” in (b) in FIG. 5 means a photosensitive dielectric layer (photosensitive insulating material layer), and “Damascene wiring” means damascene wiring.

### Second Example

A comb-shaped electrode was formed on the surface of a silicon wafer in the same manner as in the first example except that the L/S (width/space) of the trench pattern was set to 1.5 μm/1.5 μm instead of 1.2 μm/1.2 μm.

### First Comparative Example

A comb-shaped electrode was formed on the surface of a silicon wafer in the same manner as in the second example except that a metal cap was not formed on the surface of the Cu plating layer.

### Second Comparative Example

A comb-shaped electrode was formed on a surface of a silicon wafer in the same manner as in the second example except that a Ti/Cu seed layer was formed instead of forming the Ni—B seed layer as a seed layer.

### Third Comparative Example

A comb-shaped electrode was formed on the surface of the silicon wafer in the same manner as in the second example except that neither the Ni—B seed layer nor the metal cap was formed, and the inside of the trench pattern was filled with a Cu plating layer by electroless Cu plating.

### [Electrical Insulation Property Test]

Using the comb-shaped electrodes of the second example and the first to third comparative examples, the electrical insulation property was evaluated by biased-Highly Accelerated Stress Test (b-HAST). The b-HAST conditions were an applied voltage of 3.3V, a temperature of 130° C., and a relative humidity of 85%. As a result, in the second example, the electric resistance value of greater than or equal to 10⁸Ω could be maintained for 200 hours. On the other hand, in the first and third comparative examples, the electric resistance value became less than or equal to 10⁶Ω in a few hours. In the second comparative example, the electric resistance value became less than or equal to 10⁶Ω in about 60 hours.

The cross-section of the comb-shaped electrode according to the second example after the b-HAST of 200 hours was subjected to STEM analysis. As a result, no Cu dendrite or the like was observed between the wirings. In addition, from the EDX mapping, the Cu element and the Ni element were not detected in the photosensitive insulating material between the wirings, and it was demonstrated that these ion migration did not occur in the b-HAST of 200 hours.

### REFERENCE SIGNS LIST

S: support, 1: insulating material layer, 1a: recess, 3: palladium adsorption layer, 5: first electroless Ni plating layer, 7: Cu plating layer, 8: wiring layer, 8a: exposed surface, 9: second electroless Ni plating layer, 10: wiring substrate (member for semiconductor device production)

1. A method for producing a member for semiconductor device production, the method comprising:
(a) forming a recess on a surface of an insulating material layer;
(b) forming a first electroless Ni plating layer on the surface of the insulating material layer and an inner surface of the recess by electroless nickel plating;
(c) forming a Cu plating layer on the first electroless Ni plating layer;
(d) forming a wiring layer including the Cu plating layer in the recess by removing the Cu plating layer and the first electroless Ni plating layer formed on the surface of the insulating material layer; and
(e) forming a second electroless Ni plating layer on an exposed surface of the wiring layer by electroless nickel plating,
wherein the first electroless Ni plating layer contains nickel and boron, and a boron content of the first electroless Ni plating layer is 0.3 to 1.0 mass % based on a mass of the first electroless Ni plating layer.

2. The method according to claim 1, wherein the second electroless Ni plating layer contains nickel and phosphorus, and a phosphorus content of the second electroless Ni plating layer is 1 to 13 mass % based on a mass of the second electroless Ni plating layer.

3. The method according to claim 1, wherein the first electroless Ni plating layer formed in step (b) satisfies the following condition:
$$0.3 \leq T a / T \leq 1.$$
where Ta represents a thickness of the first electroless Ni plating layer formed on the inner surface of the recess, and T represents a thickness of the first electroless Ni plating layer formed on the surface of the insulating material layer.

4. The method according to claim 1, wherein step (a) includes:
(a1) curing a first insulating layer by exposing the first insulating layer formed of a negative photosensitive resin composition;
(a2) forming a second insulating layer formed of a negative photosensitive resin composition on a surface of the first insulating layer after curing;
(a3) exposing a region of the second insulating layer where the recess is to be formed; and
(a4) forming the recess by developing the second insulating layer after exposure.

5. A member for semiconductor device production comprising:
an insulating material layer;
a recess formed on a surface of the insulating material layer;
a first electroless Ni plating layer formed to cover an inner surface of the recess;
a Cu plating layer formed on a surface of the first electroless Ni plating layer and with which the recess is filled; and
a second electroless Ni plating layer formed to cover an exposed surface of the Cu plating layer,
wherein the first electroless Ni plating layer contains nickel and boron, and a boron content of the first electroless Ni plating layer is 0.3 to 1.0 mass % based on a mass of the first electroless Ni plating layer.

6. The member according to claim 5, wherein the second electroless Ni plating layer contains nickel and phosphorus, and a phosphorus content of the second electroless Ni plating layer is 1 to 13 mass % based on a mass of the second electroless Ni plating layer.

7. The member according to claim 5, wherein the recess is a groove having an opening width of 0.5 to 3 μm.

8. The member according to claim 5, wherein a thickness of the insulating material layer is less than or equal to 10 μm.
